(19) United States
(12) Patent Application Publication
(10) Pub. No.: US 2006/0027871 A1
(43) Pub. Date: Feb. 9, 2006

(54) [ELECTROSTATIC DISCHARGE PROTECTION DEVICE]

(76) Inventor: Shiao-Shien Chen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,818

(22) Filed: Aug. 5, 2004

(51) Int. Cl. H01L 23/62

(52) U.S. Cl. 257/355

(57) ABSTRACT

An electrostatic discharge (ESD) protection device including an ESD protection circuit is provided. The ESD protection circuit includes at least a diode connected in series between a first voltage and a pad, and at least an ESD component connected in series between a second voltage and a pad. Each of the at least an ESD component comprises a deep N-well region formed in a P-type substrate, a triple P-well formed in the deep N-well region, and a highly doped N-type (N+) region and a highly doped P-type (P+) region formed in the triple P-well region.

### BACKGROUND OF THE INVENTION

1. Field of the Invention

The present invention is related to an electrostatic discharge (ESD) protection device. More particularly, the present invention relates to an ESD protection device for bypassing an ESD current with low-capacitance and low substrate noise.

2. Description of Related Art

As the semiconductor technology advances, the integration of the semiconductor devices are enhanced by, for example, reducing the line width and increasing the stacked layers of the semiconductor device. However, as the area and the tolerance of the integrated circuits (IC) reduce, the damage caused by the electrostatic discharge (ESD) could become a serious problem. Conventionally, the waveform of the electrostatic discharge (ESD) has the properties of short rise time (e.g., generally between 5 ns to 15 ns) and high pulse power (e.g., generally between 1000V to 3000V). Therefore, when the integrated circuit (IC) is damaged by the ESD, the IC might get punched through or burned out suddenly.

Therefore, in order to resolve the problems described above, an ESD protection circuit is generally disposed between the input and output pads of the IC to protect the IC from the ESD damage by shunting the electrostatic charges of the ESD source from the IC. Specially, the ESD protection circuit impacts the performance of the radio frequency (RF) IC (e.g., the signal integrity, input/output (I/O) impedance matching, power efficiency and bandwidth etc.) due to the sizeable ESD induced parasitics such as the parasitic resistance and capacitance associated with the ESD protection circuit. In addition, the ESD protection circuit also introduce noise coupling due to parasitic capacitance and will generate extra noises that will affect total IC noise figures.

FIG. 1A is a schematic circuit diagram of a conventional radio frequency (RF) ESD protection circuit. Referring to FIG. 1A, an ESD protection circuit 110 is connected to an ESD power clamp circuit 102 and an internal circuit 103. The internal circuit 103 may be constructed by a PMOS transistor 104 and an NMOS transistor 106. The gate of the PMOS transistor 104 and the NMOS transistor 106 are connected to the pad 108, the source of the PMOS transistor 104 is connected to the drain of the NMOS transistor 106, the drain of the PMOS transistor 104 is connected to the voltage V_{DD}, and the source of the NMOS transistor 106 is connected to the voltage V_{SS}. The ESD protection circuit 110 includes m diodes (i.e., diodes 112a to 112m) connected between the voltage V_{DD} and the pad 108, and n diodes (i.e., diodes 114a to 114n) connected between the voltage V_{SS} and the pad 108. Accordingly, the ESD current may also be shunted from the pad 108 to V_{DD} via the diodes 112a to 112m, or from the V_{SS} to the pad 108 via the diodes 114n to 114a.

FIG. 1B is a schematic cross-sectional view illustrating the ESD protection circuit of the RF ESD protection circuit shown in FIG. 1A. Referring to FIG. 1B, each of the diodes 112a to 112m and 114a to 114n may be constructed by a N-well region formed in a P-type substrate 101, and a highly doped N-type region (N+ region) and highly doped P-type region (P+ region) formed in the N-well. It is noted that, although the diodes 112a to 112m or the diodes 114a to 114n of the ESD protection circuit 110 may be used to bypass the ESD current, however, the parasitic capacitance in the ESD protection circuit 110 is large. In general, the parasitic capacitance of each diode in the ESD protection circuit 110 is associated with the parallel connection of the parasitic capacitance C1 between the P+ region and the N-well region and the parasitic capacitance C2 between the N-well region and the P-type substrate 101. It is noted that the parasitic capacitance C2 is much larger than the parasitic capacitance C1 since the N-well region and the P-type substrate 101 are both lightly doped, and the area of the junction between the N-well region and the P-type substrate 101 is much larger than the area between the P+ region and the N-well region. It is noted that, since the parasitic capacitance C2 is connected between the pad 108 and the P-type substrate 101 directly, the input capacitance of the ESD protection circuit 110 is increased.

Therefore, the conventional RF ESD protection circuit 110 shown in FIG. 1A and FIG. 1B has the disadvantages that the parasitic capacitance of the ESD protection circuit 110 is large. It is noted that, the transmission of the RF signal may be delayed due to the large parasitic capacitance of the ESD protection circuit 110.

In order to solve the problem described above, another conventional RF ESD protection circuit is developed. FIG. 2A is a schematic circuit diagram of another conventional RF ESD protection circuit. Referring to FIG. 2A, an ESD protection circuit 210 is connected to an ESD power clamp circuit 202 and an internal circuit 203. The internal circuit 203 may be constructed by a PMOS transistor 204 and an NMOS transistor 206. The gate of the PMOS transistor 204 and the NMOS transistor 206 are connected to the input pad 208, the source of the PMOS transistor 204 is connected to the drain of the NMOS transistor 206, the drain of the PMOS transistor 204 is connected to the voltage V_{DD}, and the source of the NMOS transistor 206 is connected to the voltage V_{SS}. The ESD protection circuit 210 may be constructed by m diodes (i.e., diodes 212a to 212m, wherein m≧1) connected between the voltage V_{DD} and the pad 208 and a diode 214 connected between the voltage V_{SS} and the pad 208.

FIG. 2B is a schematic cross-sectional view illustrating the ESD protection circuit of the RF ESD protection circuit shown in FIG. 2A. Referring to FIG. 2B, each of the diodes 212a to 212m may be constructed by a N-well region formed in a P-type substrate 201, and an N+ region and a P+ region formed in the N-well region. In addition, the diode 214 is constructed by an N+ region, a P+ region and the P-type substrate 201. It is noted that, when FIG. 1B and FIG. 2B are under similar process parameters and structure dimensions, the parasitic capacitance C3 of the diode 214 is close to the parasitic capacitance C1 since the N+ region and the P+ region are highly doped, and the area of the junction between the N+ region and the P-type substrate 201 in the diode 214 is close to the area of the junction between the P+ region and the N-well region in the diode 114a. Therefore, the parasitic capacitance of the ESD protection circuit 210 is less than that of the ESD protection circuit 110 since the ESD protection circuit 210 shown in FIG. 2B does not include the parasitic capacitance C2 as the ESD protection circuit 110 shown in FIG. 1B.

It is noted that, in FIG. 213, although the parasitic capacitance of the ESD protection circuit 210 is reduced, however, a substrate noise generated from other circuits in the same substrate 201 may be coupled into the RF input mode through the diode 214 constructed by the P-type substrate 201. Therefore, the performance of the RF ESD power clamp circuit 102 is seriously degraded by the substrate noise. Accordingly, an ESD protection circuit with low-capacitance and low substrate noise is quite desirable.

### SUMMARY OF THE INVENTION

Accordingly, the present invention is directed to electrostatic discharge (ESD) protection device with low-capacitance and low substrate noise capable of bypassing an ESD current.

In addition, the present invention is also directed to electrostatic discharge (ESD) protection circuit low-capacitance and low substrate noise capable of bypassing an ESD current.

According to one embodiment of the present invention, the ESD protection circuit comprises, for example but not limited to, at least a diode connected in series between a first voltage and a pad, and at least an ESD component connected in series between a second voltage and a pad. Each of the at least an ESD component comprises a deep N-well region formed in a P-type substrate, a triple P-well formed in the deep N-well region, and a highly doped N-type (N+) region and a highly doped P-type (P+) region formed in the triple P-well region.

In one embodiment of the present invention, when a number of the ESD component is one, the N+ region of the ESD component is connected to the pad, and the P+ region of the ESD component is connected to the second voltage.

In one embodiment of the present invention, when a number of the ESD component is two including a 1^{st} ESD component and a 2^{nd} ESD component, the N+ region of a 1^{st} ESD component is connected to the pad, the P+ region of the 2^{nd} ESD component is connected to the second voltage, and the P+ region of the 1^{st} ESD component is connected to the N+ region of the 2^{nd} ESD component.

In one embodiment of the present invention, when a number of the ESD component is S including a 1^{st} ESD component to a S^{th} ESD component, the N+ region of the 1^{st} ESD component is connected to the pad, the P+ region of the S^{th} ESD component is connected to the second voltage, and the P+ region of the T^{th} ESD component is connected to the N+ region of the (T+1)^{th} ESD component, wherein S is a positive integer and T is a positive integer from 1 to S−1.

In one embodiment of the present invention, each of the at least a diode comprises a N-well region formed in a P-type substrate, and a N+ region and a P+ region formed in the N-well region.

In one embodiment of the present invention, when a number of the diode is one, the N+ region of the diode is connected to the first voltage, and the P+ region of the diode is connected to the pad.

In one embodiment of the present invention, when a number of the diode is two including a first diode and a second diode, the N+ region of a first diode is connected to the first voltage, the P+ region of the second diode is connected to the pad, and the P+ region of the first diode is connected to the N+ region of the second diode.

In one embodiment of the present invention, when a number of the diode is S including a 1^{st} diode to a S^{th} diode, the N+ region of the 1^{st} diode is connected to the first voltage, the P+ region of the S^{th} diode is connected to the pad, and the P+ region of the T^{th} diode is connected to the N+ region of the (T+1)^{th} diode, wherein S is a positive integer and T is a positive integer from 1 to S−1.

In one embodiment of the present invention, the ESD protection circuit further comprises another ESD protection circuit comprising a PMOS transistor and an NMOS transistor. A gate of the PMOS transistor and a gate of the NMOS transistor are connected to the pad, a source of the PMOS transistor is connected to a drain of the NMOS transistor, a drain of the PMOS transistor is connected to the first voltage, and a source of the NMOS transistor is connected to the second voltage.

In one embodiment of the present invention, the ESD protection device is a radio frequency (RF) ESD protection device.

According to another embodiment of the present invention, the ESD protection circuit comprises, for example but not limited to, at least a first ESD component connected in series between a first voltage and a pad, and at least a second ESD component connected in series between a second voltage and a pad. Each of the at least a first ESD component or the at least a first ESD component comprises a deep N-well region formed in a P-type substrate, a triple P-well formed in the deep N-well region, and a highly doped N-type (N+) region and a highly doped P-type (P+) region formed in the triple P-well region.

In one embodiment of the present invention, when a number of the first ESD component is one, the N+ region of the first ESD component is connected to the pad, and the P+ region of the first ESD component is connected to the second voltage.

In one embodiment of the present invention, when a number of the first ESD component is two including a 1^{st} first ESD component and a 2^{nd} first ESD component, the N+ region of a 1^{st} first ESD component is connected to the pad, the P+ region of the 2^{nd} first ESD component is connected to the second voltage, and the P+ region of the 1^{st} first ESD component is connected to the N+ region of the 2^{nd} first ESD component.

In one embodiment of the present invention, when a number of the first ESD component is S including a 1^{st} first ESD component to a S^{th} first ESD component, the N+ region of the 1^{st} first ESD component is connected to the pad, the P+ region of the S^{th} first ESD component is connected to the second voltage, and the P+ region of the T^{th} first ESD component is connected to the N+ region of the (T+1)^{th} first ESD component, wherein S is a positive integer and T is a positive integer from 1 to S−1.

In one embodiment of the present invention, when a number of the second ESD component is one, the N+ region of the second ESD component is connected to the first voltage, and the P+ region of the second ESD component is connected to the pad.

In one embodiment of the present invention, when a number of the second ESD component is two including a 1^{st} second ESD component and a 2^{nd} second ESD component, the N+ region of a 1^{st} second ESD component is connected to the first voltage, the P+ region of the 2^{nd} second ESD component is connected to the pad, and the P+ region of the 1^{st} second ESD component is connected to the N+ region of the 2^{nd} second ESD component.

In one embodiment of the present invention, when a number of the second ESD component is S including a 1^{st} second ESD component to a S^{th} second ESD component, the N+ region of the 1^{st} second ESD component is connected to the first voltage, the P+ region of the S^{th} second ESD component is connected to the pad, and the P+ region of the T^{th} second ESD component is connected to the N+ region of the (T+1)^{th} second ESD component, wherein S is a positive integer and T is a positive integer from 1 to S−1.

In one embodiment of the present invention, the ESD protection circuit further comprises another ESD protection circuit comprising a PMOS transistor and an NMOS transistor. A gate of the PMOS transistor and a gate of the NMOS transistor are connected to the pad, a source of the PMOS transistor is connected to a drain of the NMOS transistor, a drain of the PMOS transistor is connected to the first voltage, and a source of the NMOS transistor is connected to the second voltage.

In one embodiment of the present invention, the ESD protection device is a radio frequency (RF) ESD protection device.

Accordingly, since the ESD component is provided for the ESD protection circuit of the present invention, the parasitic capacitance of the ESD protection circuit is much less than that of the conventional RF ESD protection circuits. In addition, since the ESD component dose not constructed by the substrate of the ESD protection circuit, the problem of the substrate noise may be reduced.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic circuit diagram of a conventional RF ESD protection circuit.

FIG. 1B is a schematic cross-sectional view illustrating the ESD protection circuit of the RF ESD protection circuit shown in FIG. 1A.

FIG. 2A is a schematic circuit diagram of another conventional RF ESD protection circuit.

FIG. 2B is a schematic cross-sectional view illustrating the ESD protection circuit of the RF ESD protection circuit shown in FIG. 2A.

FIG. 3A is a schematic circuit diagram of a RF ESD protection circuit according to one embodiment of the present invention.

FIG. 3B is a schematic cross-sectional view illustrating the ESD protection circuit of the RF ESD protection circuit according to one embodiment of the present invention.

FIG. 3C is a schematic circuit diagram of an ESD protection circuit according to one embodiment of the present invention.

FIG. 3D is a schematic cross-sectional view illustrating an ESD protection circuit of an ESD protection circuit according to one embodiment of the present invention.

FIG. 4 is a diagram illustrating the parasitic capacitance of the ESD protection circuit of the present invention and the conventional RF ESD protection circuit versus the number of the ESD components or diodes thereof.

FIG. 5A is a schematic circuit diagram of a RF ESD protection circuit according to one embodiment of the present invention.

FIG. 5B is a schematic cross-sectional view illustrating the ESD protection circuit of the RF ESD protection circuit according to one embodiment of the present invention.

FIG. 5C is a schematic circuit diagram of an ESD protection circuit according to one embodiment of the present invention.

FIG. 5D is a schematic cross-sectional view illustrating an ESD protection circuit of an ESD protection circuit according to one embodiment of the present invention.

### DESCRIPTION OF EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

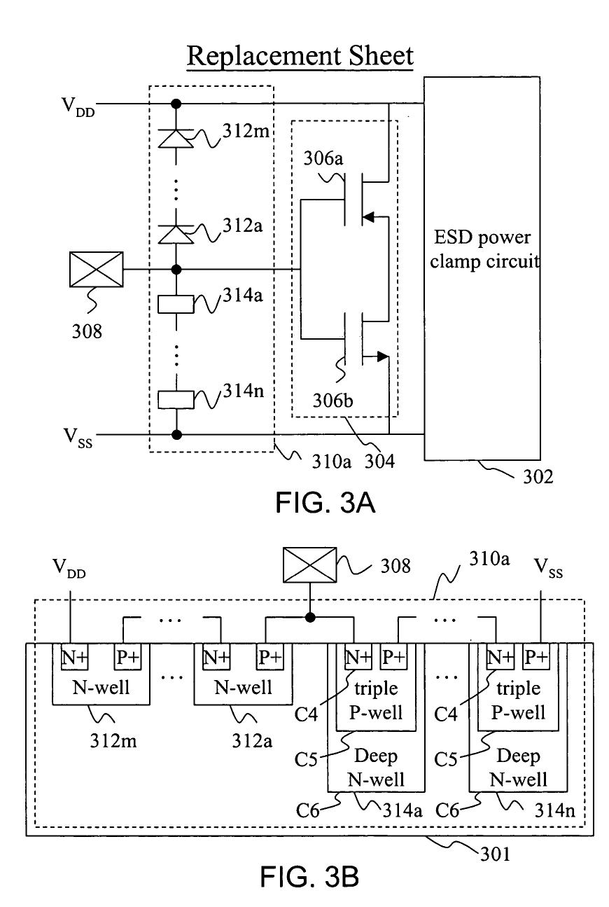

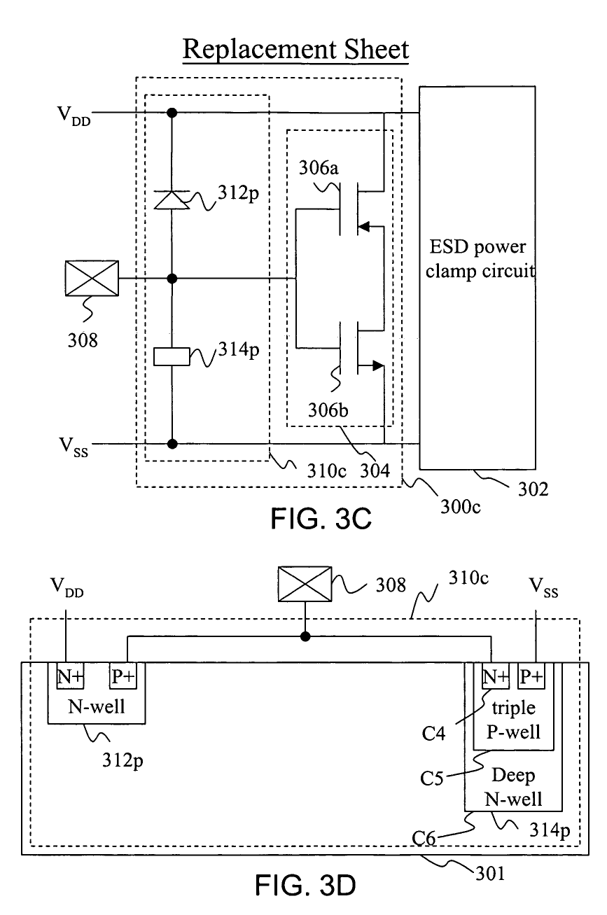

FIG. 3A is a schematic circuit diagram of an ESD protection circuit according to one embodiment of the present invention. Referring to FIG. 3A, an ESD protection circuit 310a is connected to an ESD power clamp circuit 302 and an internal circuit 304 between voltages V_{DD} and V_{SS}. In one embodiment of the present invention, the voltages V_{DD} and V_{SS} represent a high voltage and a low voltage or vice versa. Be ESD protection circuit 310a comprises, for example but not limited to, at least a diode connected between voltage V_{DD} and the input pad 308, and at least an ESD component connected between voltage V_{SS} and the pad 308.

FIG. 3B is a schematic cross-sectional view illustrating an ESD protection circuit of an ESD protection circuit according to one embodiment of the present invention. Referring to FIG. 3A, at least a diode (e.g., m diodes 312a to 312m are shown in FIG. 3B, wherein m≧1) is connected in series between voltage V_{DD} and the pad 308, and at least an ESD component (e.g., n ESD components 314a to 314n are shown in FIG. 3B, wherein n≧1) is connected in series between voltage V_{SS} and the pad 308. Referring to FIG. 3B, each of the diodes 312a to 312m comprises, for example but not limited to, a N-well region formed in a P-type substrate 301, and a highly doped N-type region (N+ region) and a highly doped P-type region (P+ region) formed in the N-well region. In one embodiment of the present invention, the ESD protection circuit 310a may comprise only two diodes (e.g., diodes 312a and 312m). Thus, the P+ region of the diode 312a is connected to the pad 308, the N+ region of the diode 312m is connected to voltage V_{DD}, and the N+ region of the diode 312a is connected to the P+ region of the diode 312m.

Referring to FIG. 3B, each of the ESD components 314a to 314n comprises, for example but not limited to, a deep N-well region formed in the P-type substrate 301, a triple P-well formed in the deep N-well region, and an N+ region and a P+ region formed in the triple P-well region. In one embodiment of the present invention, the ESD protection circuit 310a may comprise only one ESD components e.g., ESD components 314p) connected between the pad 308 and the V_{SS}. Thus, the N+ region of the ESD component 314a is connected to the pad 308, the P+ region of the ESD component 314a is connected to voltage V_{SS}, and the P+ region of the ESD component 314a is connected to the N+ region of the ESD component 314n.

FIG. 3C is a schematic circuit diagram of an ESD protection circuit according to one embodiment of the present invention when m=1 and n=1. Referring to FIG. 3C, the ESD protection circuit 310ccomprises, for example but not limited to, one diode 312p connected between voltage V_{DD} and the pad 308, and one ESD component 314p connected between voltage V_{SS} and the pad 308.

FIG. 3D is a schematic cross-sectional view illustrating an ESD protection circuit of an ESD protection circuit according to one embodiment of the present invention when m=1 and n=1. Referring to FIG. 3D, the diode 312p comprises, for example but not limited to, a N+ region and a P+ region formed in a N-well region in a P-type substrate 301. The P+ region of the diode 312p is connected to the pad 308, and the N+ region of the diode 312p is connected to voltage V_{DD}. The ESD components 314p comprises, for example but not limited to, a deep N-well region formed in the P-type substrate 301, a triple P-well formed in the deep N-well region, and an N+ region and a highly doped P-type region formed in the triple P-well region. The N+ region of the ESD component 314p is connected to the pad 308, and the P+ region of the ESD component 314p is connected to voltage V_{SS}.

It should be noted tat, the ESD protection circuit 310a shown in FIG. 3A and FIG. 3B or the ESD protection circuit 310c shown in FIG. 3C and FIG. 3D is only illustrate as an exemplary example, and should not be adopted for limiting the scope of the present invention. In the present invention, the ESD protection circuit may comprise, for example but not limited to, one or more diode connected between voltage V_{DD} and the pad 308, and one or more ESD component connected between voltage V_{SS} and the pad 308.

In one embodiment of the present invention, the ESD protection circuit 310a or 310c may be adopted for a RF ESD protection circuit.

In one embodiment of the present invention, the ESD protection circuit 310a or 310c further comprises an internal circuit 304. The internal circuit 304 comprises, for example but not limited to, a PMOS transistor 306a and an NMOS transistor 306b. The gate of the PMOS transistor 306a and an NMOS transistor 306b are connected to the pad 308, the source of the PMOS transistor 306a is connected to the drain of the NMOS transistor 306b, the drain of the PMOS transistor 306a is connected to the voltage V_{DD}, and the source of the NMOS transistor 306b is connected to the voltage V_{SS}.

Referring to FIG. 3B or 3D, the parasitic capacitance of the ESD components 314a to 314n or 314p is associated with the series connection of the parasitic capacitance C4 between the N+ region and the triple P-well region, the parasitic capacitance C5 between the triple P-well region and the deep N-well region, and the parasitic capacitance C6 between the deep N-well region and the P-type substrate 301. The parasitic capacitance C4 is much less than the parasitic capacitance C5 or C6 since the N+ region is highly doped and the area of the junction between the N+ region and the triple P-well region is much less than the area of the junction between the triple P-well region and the deep N-well region, or the area of the junction between the deep N-well region and the P-type substrate 301. Therefore, since the parasitic capacitance of the ESD components 314a to 314n shown in FIG. 31 or the ESD component 314p shown in FIG. 3D is associated with the series connection of the junction capacitances C4, C5 and C6, the parasitic capacitance of the ESD protection circuit 310a or 310c between the pad 308 and the P-type substrate 301 may be reduced.

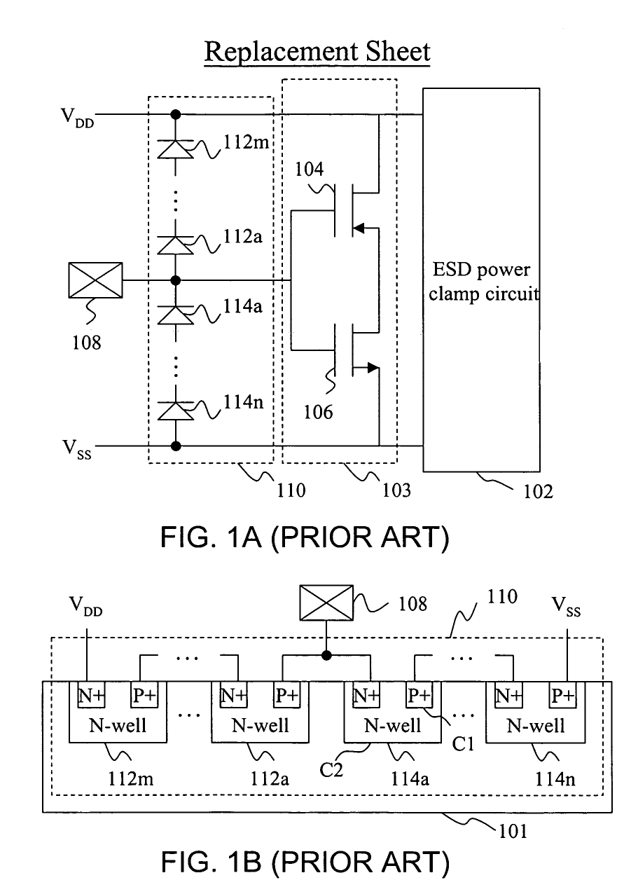

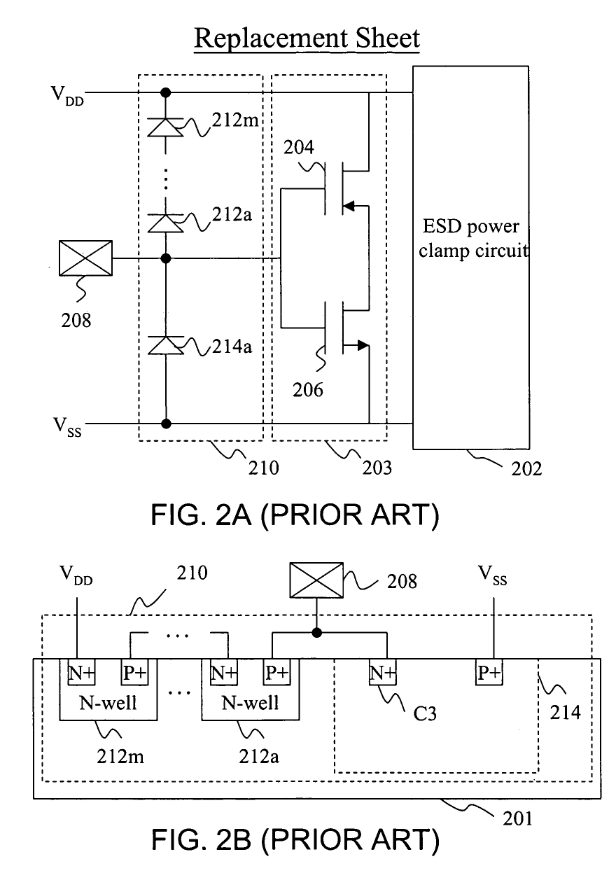

It should be noted that, when FIG. 3B, FIG. 3D and FIG. 2B (or FIG. 1B) are under similar process parameters and structure dimensions, the parasitic capacitance C4 is close to the parasitic capacitance C3 (or C1) since the area of the junction between the N+ region and the triple P-well in the ESD components 314a to 314n shown in FIG. 3B or the ESD component 314p shown in FIG. 3D is close to the area of the junction between the N+ region and the P-type substrate 201 (or the area of the junction between the P+ region and the N-well region). Therefore, the parasitic capacitance of the ESD protection circuit 310a or 310c (less than the junction capacitances C4) is less than the parasitic capacitance C3 of the diode 214 or less than me parasitic capacitance of the series connection of the diodes 114a to 114n. Accordingly, the parasitic capacitance of the ESD protection circuit 310a or 310c is less than that of the ESD protection circuit 210 or the ESD protection circuit 110.

In addition, when FIG. 3B and FIG. 3D are under similar process parameters and structure dimensions, the parasitic capacitance of the series connection of the ESD components 314a to 314n shown in FIG. 3B is less than the parasitic capacitance of the ESD component 314p shown m FIG. 3D. Accordingly, the parasitic capacitance of the ESD protection circuit 310a is much less than that of the ESD protection circuit 210 or the ESD protection circuit 110.

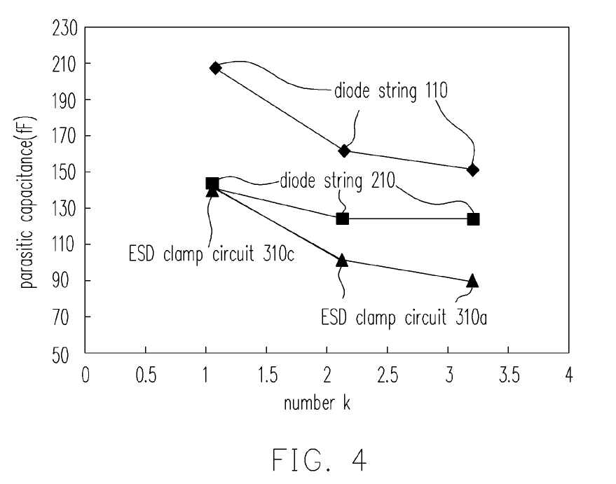

FIG. 4 is a diagram illustrating the parasitic capacitance of the ESD protection circuit of the present invention and the conventional ESD protection circuit versus the number of the ESD components or diodes thereof. In FIG. 4, the uppermost line represents the parasitic capacitance of the conventional ESD protection circuit 110 including k diodes 112a to 112m (i.e., m=k) and k diodes 114a to 114n (i.e., n=k), wherein k=1, 2, or 3. The middle line represents the parasitic capacitance of the conventional ESD protection circuit 210 including k diodes 212a to 212m (i.e., m=k) and one diodes 214a, wherein k=1, 2, or 3. The lowermost line represents the parasitic capacitance of the ESD protection circuit 310a comprising k diode 312a to 312m (i.e., m=k) and k ESD components 314a to 314n (i.e., n=k) as shown in FIG. 3B, wherein k=1, 2, or 3. It should be noted that, the ESD protection circuit 310a has the lowest parasitic capacitance compared to that of the conventional RF ESD protection circuit 110 or 210.

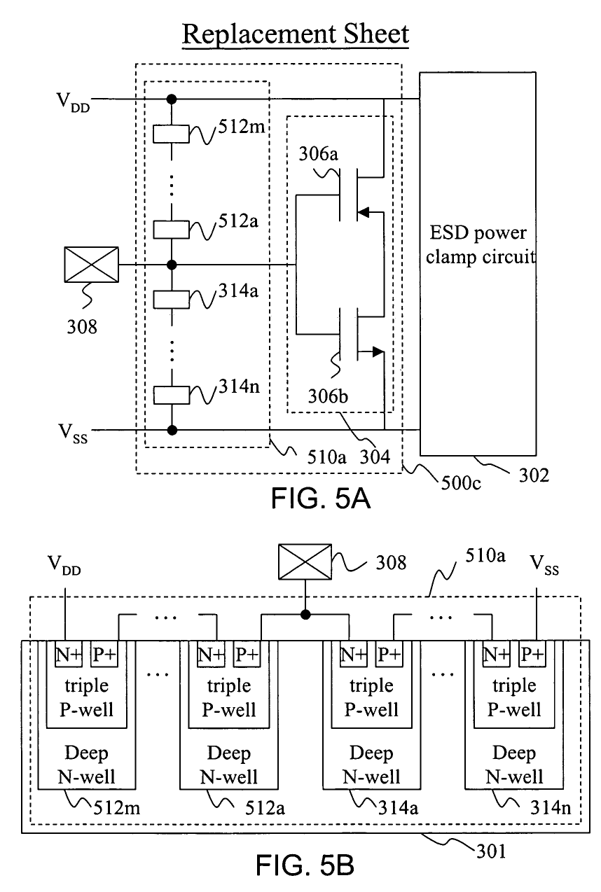

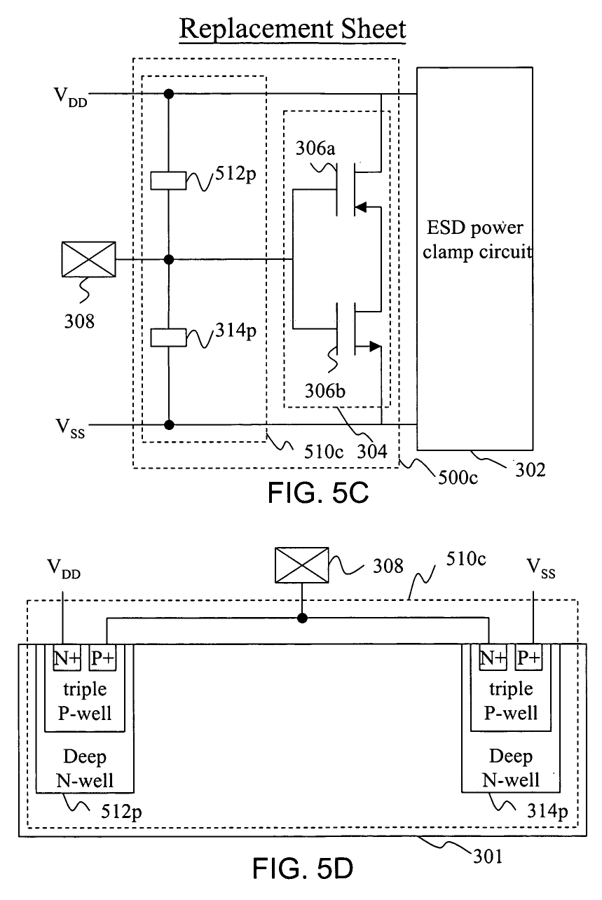

FIG. 5A is a schematic circuit diagram of an ESD protection circuit according to one embodiment of the present invention. FIG. 5B is a schematic cross-sectional view illustrating an ESD protection circuit of an ESD protection circuit according to one embodiment of the present invention The ESD protection circuit 510a shown in FIG. 5A and FIG. 5B is similar to the ESD protection circuit 310a shown in FIG. 3A and FIG. 3B except for that the diodes 312a to 312m of the ESD protection circuit 310a is replaced by the ESD components 512a to 512m of the ESD protection circuit 510a.

FIG. 5C is a schematic circuit diagram of an ESD protection circuit according to one embodiment of the present invention as m=n=1. FIG. 5D is a schematic cross-sectional view illustrating an ESD protection circuit of an ESD protection circuit according to one embodiment of the present invention as m=n=1. The ESD protection circuit 510c shown in FIG. 5C and FIG. 5D is similar to the ESD protection circuit 310c shown in FIG. 3C and FIG. 3D except for that the diodes 312p of the ESD protection circuit 310c is replaced by the ESD components 512p of the ESD protection circuit 510c.

It should be noted that, when FIG. 5D and FIG. 3D are under similar process parameters and structure dimensions, the parasitic capacitance of the series connection of the ESD component 512p shown in FIG. 5D is less than the parasitic capacitance of the ESD component 312p shown in FIG. 3D.

In addition, when FIG. 5B and FIG. 3B are under similar process parameters and structure dimensions, the parasitic capacitance of the series connection of the ESD components 512a to 512m shown in FIG. 5B is less than the parasitic capacitance of the ESD components 312a to 312m shown in FIG. 3B. Thus, the parasitic capacitance of the ESD protection circuit 510a is less than that of the ESD protection circuit 310a. Accordingly, the parasitic capacitance of the ESD protection circuit 510a is much less than that of the ESD protection circuit 210 or the ESD protection circuit 110.

Accordingly, since the ESD component is provided for the ESD protection circuit of the ESD protection circuit of the present invention, the parasitic capacitance of the ESD protection circuit is much less than that of the conventional RF ESD protection circuit, In addition, since the ESD component dose not constructed by the substrate of the ESD protection circuit of the ESD protection circuit, the problem of the substrate noise may be reduced.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An electrostatic discharge (ESD) protection device, comprising:
an ESD protection circuit, comprising:
at least a diode connected in series between a first voltage and a pad; and
at least an ESD component connected in series between a second voltage and a pad, wherein each of the at least an ESD component comprises a deep N-well region formed in a P-type substrate, a triple P-well formed in the deep N-well region, and a highly doped N-type (N+) region and a highly doped P-type (P+) region formed in the triple P-well region.

2. The ESD protection device of claim 1, wherein when a number of the ESD component is one, the N+ region of the ESD component is connected to the pad, and the P+ region of the ESD component is connected to the second voltage.

3. The ESD protection device of claim 1, wherein when a number of the ESD component is two including a 1^{st} ESD component and a 2^{nd} ESD component, the N+ region of a 1^{st} ESD component is connected to the pad, the P+ region of the 2^{nd} ESD component is connected to the second voltage, and the P+ region of the 1^{st} ESD component is connected to the N+ region of the 2^{nd} ESD component.

4. The ESD protection device of claim 1, wherein when a number of the ESD component is S including a 1^{st} ESD component to a S^{th} ESD component, the N+ region of the 1^{st} ESD component is connected to the pad, the P+ region of the S^{th} ESD component is connected to the second voltage, and the P+ region of the T^{th} ESD component is connected to the N+ region of the (T+1)^{th} ESD component, wherein S is a positive integer and T is a positive integer from 1 to S−1.

5. The ESD protection device of claim 1, wherein each of the at least a diode comprises a N-well region formed in a P-type substrate, and a N+ region and a P+ region formed in the N-well region.

6. The ESD protection device of claim 1, wherein when a number of the diode is one, the N+ region of the diode is connected to the first voltage, and the P+ region of the diode is connected to the pad.

7. The ESD protection device of claim 1, wherein when a number of the diode is two including a first diode and a second diode, the N+ region of a first diode is connected to the first voltage, the P+ region of the second diode is connected to the pad, and the P+ region of the first diode is connected to the N+ region of the second diode.

8. The ESD protection device of claim 1, wherein when a number of the diode is S including a 1^{st} diode to a S^{th} diode, the N+ region of the 1^{st} diode is connected to the first voltage, the P+ region of the S^{th} diode is connected to the pad, and the P+ region of the T^{th} diode is connected to the N+ region of the (T+1)^{th} diode, wherein S is a positive integer and T is a positive integer from 1 to S−1.

9. The ESD protection device of claim 1, wherein the ESD protection device farther comprises another ESD protection circuit comprising:
a PMOS transistor; and
an NMOS transistor, wherein a gate of the PMOS transistor and a gate of the NMOS transistor are connected to the pad, a source of the PMOS transistor is connected to a drain of the NMOS transistor, a drain of the PMOS transistor is connected to the first voltage, and a source of the NMOS transistor is connected to the second voltage.

10. The ESD protection device of claim 1, wherein the ESD protection device is a radio frequency (RF) ESD protection device.

11-19. (canceled)
